(19) United States
(12) Patent Application Publication
(10) Pub. No.: US 2002/0061248 A1
(43) Pub. Date: May 23, 2002

(54) High productivity semiconductor wafer processing system

(75) Inventor: Avi Tepman, Cupertino, CA (US)

Correspondence Address: Patent Counsel, Applied Materials, Inc., 3050 Bowers Avenue, P.O. Box 450A, Santa Clara, CA, 95052, US

(73) Assignee: APPLIED MATERIALS, INC.

(21) Appl. No.: 09/895,805

(22) Filed: Jun. 29, 2001

Related U.S. Application Data
(60) Provisional application No. 60/216,792, filed on Jul. 7, 2000.

(51) Int. Cl. C23C 16/00; B66C 23/00

(52) U.S. Cl. 414/744.5; 118/719

(57) ABSTRACT

A system and method for transferring a wafer between chambers is provided. Generally, the system includes a first chamber abutting a first wall of a transfer chamber. The transfer chamber includes at least a first transfer robot having a central axis of rotation disposed therein. The first chamber includes a substrate receiving member that is adapted to support the wafer centered on a central axis of the wafer receiving member. The support member is positioned such that a line defined between the central axis of the robot and central axis of the wafer receiving member is disposed at an acute angle relative to the first sidewall.

This application claims benefit of U.S. Provisional Application No. 60/216,792, filed Jul. 7, 2000, which is hereby incorporated by reference in its entirety.

### BACKGROUND OF THE INVENTION

1. Field of the Invention

The present invention relates to a multichamber, single processing system having high throughput.

2. Background of the Related Art

In the field of semiconductor processing, integrated processing systems are used to deposit and remove various conducting and dielectric materials onto and from substrates. These processing systems are typically vacuum processing systems that are generally either single wafer processing systems or batch wafer processing systems. Single wafer systems are systems that include processing chambers which receive and process a single wafer at a time. Batch wafer processing systems are systems in which multiple wafers are introduced into a chamber and processed simultaneously. It is believed by some in the industry that single wafer systems provide better control over processing control and uniformity by providing better control over gas flow uniformity and plasma, among other process parameters. Others believe that variations in process uniformity in batch processing systems is minimal and is offset by an increase in the number of substrates processed per unit of time (i.e., throughput).

To combine the benefits of both single and batch wafer processing, some semiconductor wafer processing systems combine single wafer processing chambers with batch wafer transfer. These systems comprise a centrally located transfer chamber and a plurality of processing chambers coupled to the transfer chamber. One or more wafer transfer robots are located in the transfer chamber to facilitate movement of the wafers from chamber to chamber.

In operation, unprocessed wafers are typically loaded into a load lock chamber. The transfer robots access the load lock chamber and move the wafers to the process chambers. Once processed, the wafers are moved from the process chambers back to the load lock chamber. The load lock chamber and each process chamber are accessed by one robot at a time. Even when multiple robots are used in the transfer chamber, each robot is used to access a single wafer in a single load lock chamber. Such single wafer accesses can create bottlenecks in the process throughput because one robot must wait for another robot to access a load lock chamber.

Therefore, there is a need for a system that efficiently introduces wafers into a processing system and transferring those substrates to various chambers within the system.

### SUMMARY OF THE INVENTION

One aspect of the present invention generally provides an apparatus and a method for processing semiconductor substrates. In one embodiment, the invention provides a load lock chamber having a slit valve that is sized to allow simultaneous access by two robots to the load lock chamber. In another embodiment, the invention provides a load lock chamber having a slit valve that is positioned off-center with respect to a center of a wall of the load lock chamber in which the slit valve is disposed.

In another embodiment, a system for transferring one or more substrates between a first chamber and a second chamber generally includes a first chamber abutting a first wall of a transfer chamber. The transfer chamber includes at least a first transfer robot having a central axis of rotation disposed therein. The first chamber includes a substrate receiving member that is adapted to support the wafer centered on a central axis of the wafer receiving member. The support member is positioned such that a line defined between the central axis of the robot and central axis of the wafer receiving member is disposed at an acute angle relative to the first sidewall.

In another aspect of the invention, a method for processing semiconductor substrates is provided. In one embodiment, the method for processing semiconductor substrates comprises loading two or more substrates into one or more load lock chambers, simultaneously removing a plurality of substrates from a single load lock chamber using a plurality of independently operable robots that simultaneously extend through a slit valve disposed in a wall of the load lock chamber, and moving the substrates into one or more processing chambers using the robots. In another embodiment, the method for processing semiconductor substrates comprises loading two or more substrates into one or more load lock chambers, removing a plurality of substrates from a load lock chamber using a plurality of independently operable robots that extend through a slit valve that is positioned off-center with respect to a center of a wall of the load lock chamber in which the slit valve is disposed, and moving the substrates into one or more processing chambers using the robots.

In another embodiment, a method of transferring wafers between a transfer chamber and a first chamber includes providing a transfer chamber having a first transfer robot disposed therein, the transfer chamber having a first wall containing an aperture for accessing a first chamber, and extending a first blade of the first wafer transfer robot at an acute angle relative to the first wall of the transfer chamber along a path from a retracted position within the transfer chamber to an extended position in the first chamber.

### BRIEF DESCRIPTION OF THE DRAWINGS

So that the manner in which the above recited features, advantages and objects of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 is a top plan view of one embodiment of a processing system according to the present invention;

FIG. 2 is a perspective view of one embodiment of a load lock chamber;

FIG. 3 is a perspective view of another embodiment of a load lock chamber;

FIG. 4 is a perspective view illustrating one embodiment of a pair of robots in a partially retracted position;

FIG. 5 is a partial top plan view of the processing system of FIG. 2 showing one robot extended into a load lock chamber and one robot in a partially retracted position;

FIG. 6 is a partial top plan view of the processing system of FIG. 2 showing the robots extended into a pair of processing chambers; and

FIG. 7 is a partial perspective view illustrating one embodiment of the robots in a partially extended position within a transfer chamber.

### DETAILED DESCRIPTION OF THE PREFERRED EMBODIMENT

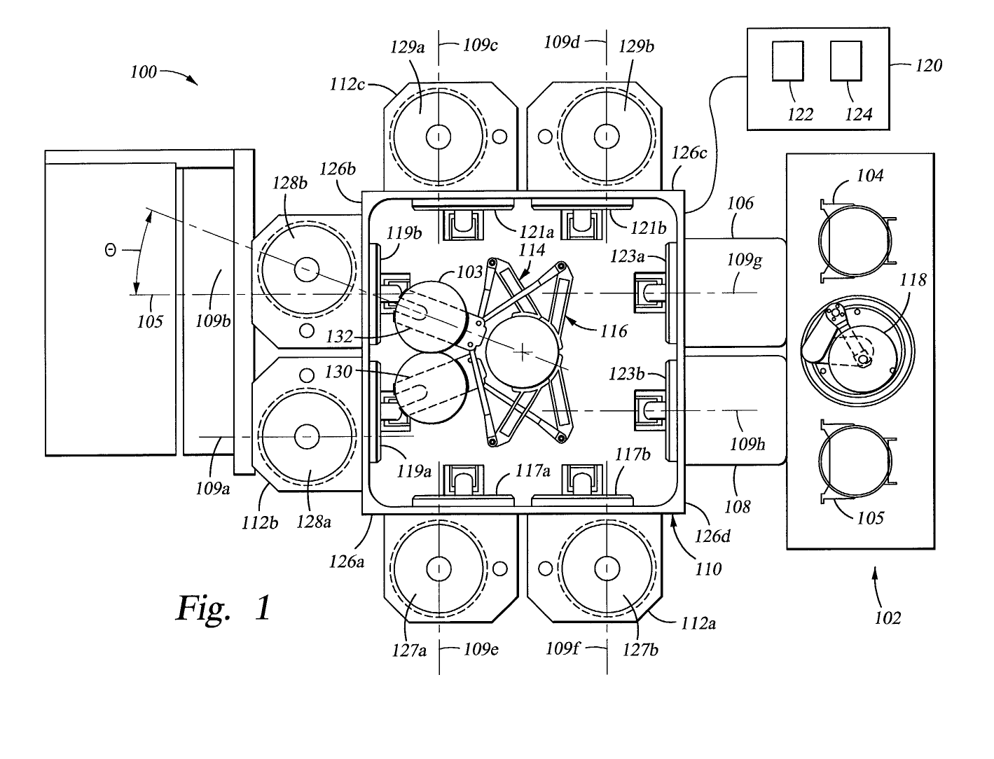

FIG. 1 is a top plan view illustrating one embodiment of a processing system 100. The processing system 100 generally includes a front-end module 102 for receiving substrate cassettes 104, 105, first and second load lock chambers 106, 108, a transfer chamber 110, three pairs of processing chambers 112a-c that each include two processing regions 127a-b, 128a-b, 129a-b, two robots 114, 116 disposed in the transfer chamber 110, and a gas panel (not shown) for supplying gases to the system 100. The word “substrate” and the word “wafer” will be used interchangeably herein. The details of the front-end module 102, the transfer chamber 110, the pairs of processing chambers 112a-c, and the gas panel are disclosed by Maydan, et al. in U.S. Pat. No. 5,855,681 issued Jan. 5, 1999, which is hereby incorporated by reference in its entirety.

The transfer chamber 110 has four sides 126a-d, or facets, defining a square. Each of the three pair of processing chambers 112a-c is connected to a side 126a-c. Two independently pressure controlled load lock chambers 106, 108 are connected to a fourth side 126d (mounting plane). Alternatively, additional processing chambers can be connected to each of the sides 126a-c. Also contemplated are processing system configurations other than a processing system having a square transfer chamber having four sides, such as a processing system having a polygonal transfer chamber with more than four sides, and having a plurality of processing chambers each connected to a side and at least one load lock chamber connected to a side.

Preferably, a system controller 120, such as a programmable computer having one or more central processing units (CPUs) 122 and support circuitry containing memory 124 (a computer readable medium) for storing associated control software is responsible for automated control of various processing sequences through bi-directional communication with the various components of the system 100 handled by signal cables (not shown).

Openings 117a-b, 119a-b, 121a-b, 123a-b provide access for the robots 114, 116 to extend into the processing regions 127a-b, 128a-b, 129a-b and the load lock chambers 106, 108 to retrieve and replace wafers 103. Each opening 117a-b, 119a-b, 121a-b, 123a-b is positioned off-center with respect to an axis 109a-h extending perpendicularly to a side and over the center of the location where a wafer is placed within the processing region 127a-b, 128a-b, 129a-b or load lock chamber 106, 108 into which the opening 117a-b, 119a-b, 121a-b, 123a-b provides access. For example, opening 119b is positioned off-center with respect to axis 109b that extends over the center of the substrate support member within processing region 128b to enable angular extension of robot 116 into processing region 128b. The positioning of the openings 117a-b, 119a-b, 121a-b, 123a-b enables angular extension of the robot blades 130,132 into the load lock chambers 106, 108 and the processing regions 127a-b, 128a-b, 129a-b

In the embodiment shown in FIG. 1, two concentric robots 114, 116 are disposed in the transfer chamber 110. Each of these robots 114, 116 operates independently. The robot pair is referred to as over/under independent (OUI) type robots. In operation, the robots 114, 116 extend into a processing region 127a-b, 128a-b, 129a-b of processing chambers, or a load lock chamber at an angle relative to an axis 109a-h extending perpendicularly to the side onto which a process chamber or a load lock chamber is connected. For example, robot 116 extends at an angle θ with respect to axis 105 extending perpendicularly to side 126b.

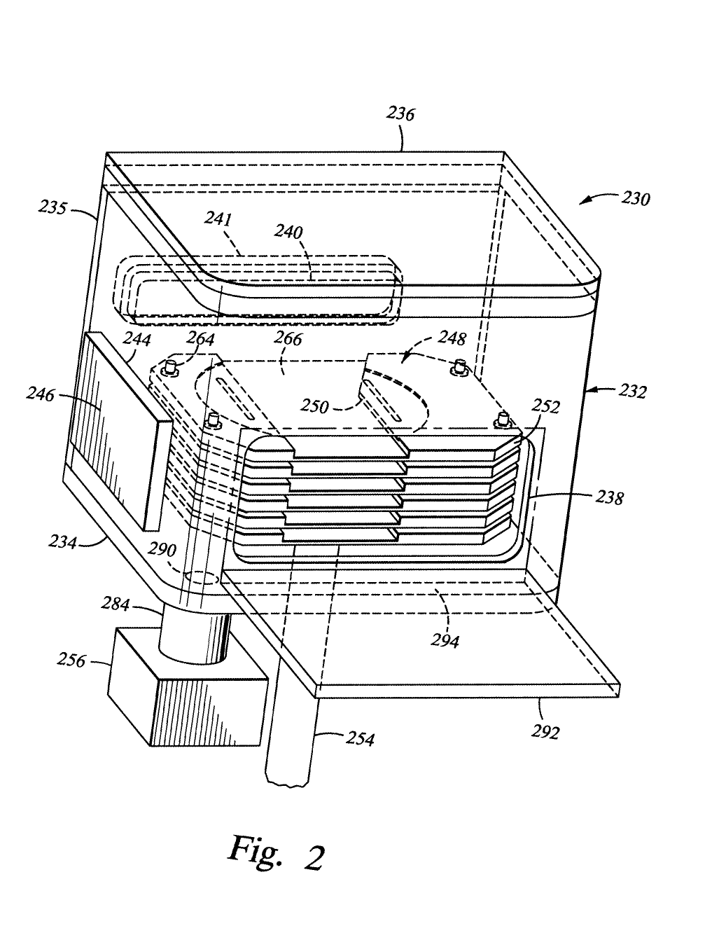

FIG. 2 shows a perspective view of one embodiment of a load lock chamber 230 of the invention. The load lock chamber 230 includes a sidewall 232, a bottom 234 and a lid 236. The sidewall 232 defines a load lock loading port 238 providing access to and from the front-end module 102 (shown in FIG. 1) for loading wafers into and unloading wafers out of the wafer cassette 248 disposed therein. The loading port 238 is sized to enable passage of at least a single wafer into the load lock chamber 230 using front-end robot 118. A loading port door 292, such as a VAT type door, may be connected to the chamber sidewall 232 by a connector such as a hinge 294 to allow the loading port door 292 to be positioned in an open position, as shown, to allow loading or unloading of wafers into the cassette 248, or in a closed position, as shown in phantom, to provide vacuum sealing of the load lock chamber 230 from the front end module 102.

An opening 240 is disposed in wall 235 of the sidewall 232 opposite the loading port 238 to allow wafers to be moved by robots 114, 116 between the load lock chamber 230 and the transfer chamber 110 (shown in FIG. 1). The opening 240 is sized to enable at least two wafer handlers (i.e., the robots 114, 116), operating in parallel planes atop one another, to extend therethrough at an angle relative an axis (109g-h of FIG. 1) extending perpendicular to wall 235. In the embodiment shown in FIG. 2, opening 240 is sized to enable simultaneous passage of two wafers in a spaced apart, parallel configuration. As shown, opening 240 is positioned horizontally off-center with respect to the center of wall 235, to allow extension of a robot into the load lock chamber 230 at an angle relative to the axis extending perpendicular to wall 235. Alternatively, the opening 240 may be positioned horizontally symmetric with respect to wall 235 but sized with sufficient width so that a robot can extend therethrough at an angle relative to the axis extending perpendicular to wall 235.

In addition to opening 240 and loading port 238, a service port 244 and service door or window 246 are disposed on one end of the load lock chamber 230 to provide service and/or visual access to the interior of the load lock chamber 230.

A valve member, such as a slit valve 241, and an actuator, such as a linear or rotary actuator, are used to seal the opening 240 and the loading port 238 when isolation or load lock vacuum is desired. Slit valves can be mounted in the bottom of the transfer chamber 110. Slit valves and methods of controlling slit valves are disclosed by Tepman, et al. in U.S. Pat. No. 5,226,632 and by Lorimer in U.S. Pat. No. 5,363,872, both of which are hereby incorporated by reference in their entirety.

The wafer cassette 248 is disposed within the load lock chamber 230 and supports wafers on wafer seats 250. In the embodiment shown in FIG. 2, six wafer seats 250 are provided. However, the invention contemplates alternative embodiments in which any number of wafer seats are provided. The wafer seats 250 are formed on cassette plates 252 of the cassette 248. The outer edges of the plates 252 are supported in a spaced relationship to one another by spacers (not shown). These spacers space the wafers from one another by about 0.6 inches. The spacers are positioned between the cassette plates 252 and secured thereto with fasteners such as screws or pins 264. Each plate 252 includes a central channel 266 formed into each plate 252 to form a slot for a robot blade to pass under a wafer when the wafer is supported on the seat 250, or for a robot blade to place a wafer on or remove a wafer from the wafer seat 250. The plates 252 and the wafer seats 250 are spaced so that at least two wafer handlers, or robot blades, can simultaneously pass between two wafer seats to place or remove the wafers from the wafer cassette 248.

The wafer cassette 248 is preferably supported on a vertically movable shaft 254. Preferably, the shaft 254 is made of anodized aluminum. The shaft 254 is disposed through the bottom 234 of the load lock chamber 230 and supports the cassette 248 within the load lock chamber 230. A motor (not shown), such as a stepper motor, linear actuator, ball screw, pneumatic cylinder or other elevator system, is disposed below the bottom 234 of the load lock chamber 230 and moves the shaft 254 vertically within the load lock chamber 230 to move the cassette 248 supported thereon vertically to locate a wafer or wafers each on a separate transfer plane, i.e., each in alignment with a wafer handler, for loading or unloading wafers in the load lock chamber 230.

An on-board vacuum pump 256, such as a roughing pump or a turbo molecular pump, is mounted to the frame (not shown) of the processing system 100 adjacent the load lock chamber 230 and the transfer chamber 110 to pump the load lock chamber 230, or to pump both the load lock chamber 230 and the transfer chamber 110 to a desired pressure. An exhaust port 290 is formed in the bottom of the load lock chamber 230 and is connected to the pump via vacuum line 284. The pump 256 is preferably a high vacuum turbo molecular pump capable of providing milliTorr pressures with very low vibration. A valve (not shown) can be disposed along the vacuum line 284 to provide pressure control within the load lock chamber 230. Each load lock chamber in the system 100 may include a separate vacuum pump or may share a common vacuum pump. One vacuum pump that may be utilized is available from Edward High Vacuum. The transfer chamber 110 is pumped to a transfer pressure through the load lock chamber 230 by opening 240 and pumping gases through the exhaust port 290 located in the load lock chamber 230. Alternately, the transfer chamber 110 can be separately pumped by a vacuum pump and can include a purge gas source, such as a nitrogen purge gas source, connected thereto. Processing systems having various configurations and pumping schemes can be used with various aspects of the invention.

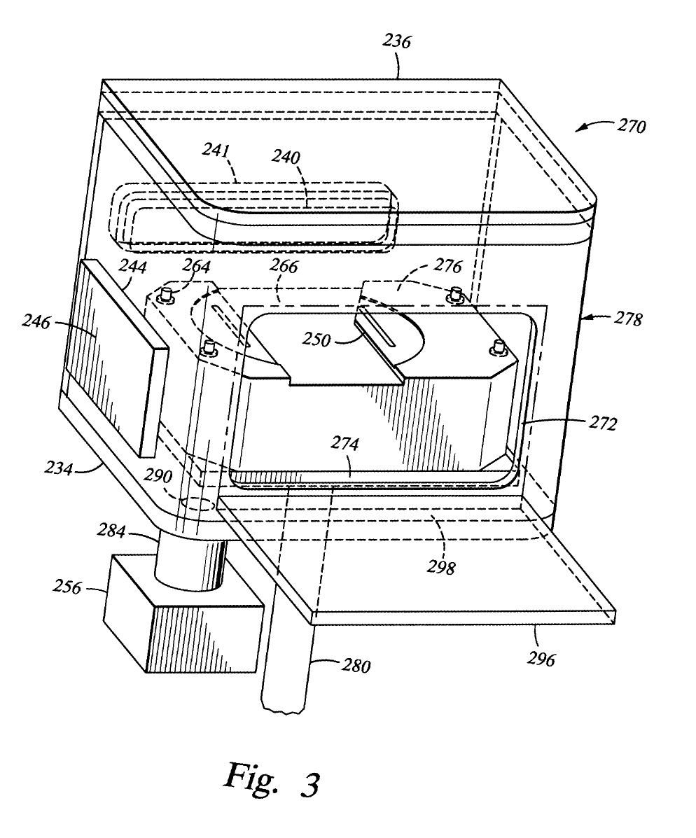

FIG. 3 shows a perspective view of another embodiment of a load lock chamber 270 of the present invention. This embodiment of the load lock chamber 270 is similar to the embodiment shown in FIG. 2, except that load lock chamber 270, including the sidewall 278, loading port 272 and the hinge 298, is configured to enable a cassette 276 containing a plurality of wafers to be loaded into and removed from the load lock chamber 270 through the loading port 272. A shaft 280 is disposed through the bottom 234 of the chamber 270 and supports a platform 274 disposed within the chamber 270 for receiving the cassette 276 containing a plurality of wafers. An actuator (not shown) moves the shaft 280 vertically within the load lock chamber 270 to move the platform 274 and the cassette 276 supported thereon vertically to locate a wafer or wafers each on separate transfer planes. Opening 240 is sized sufficiently large to enable simultaneous access of two wafers from the wafer cassette by robots 114,116.

Other embodiments of load lock chambers are described in U.S. Pat. No. 6,048,154 issued Apr. 11, 2000, U.S. Pat. No. 5,961,269, issued Oct. 5, 1999 and U.S. Pat. No. 5,882,165, issued Mar. 16, 1999, each of which is incorporated herein by reference in its entirety. Each of these illustrative load locks can be modified to increase the size of the slit valve to accommodate simultaneous access to a plurality of substrates in accordance with the present invention.

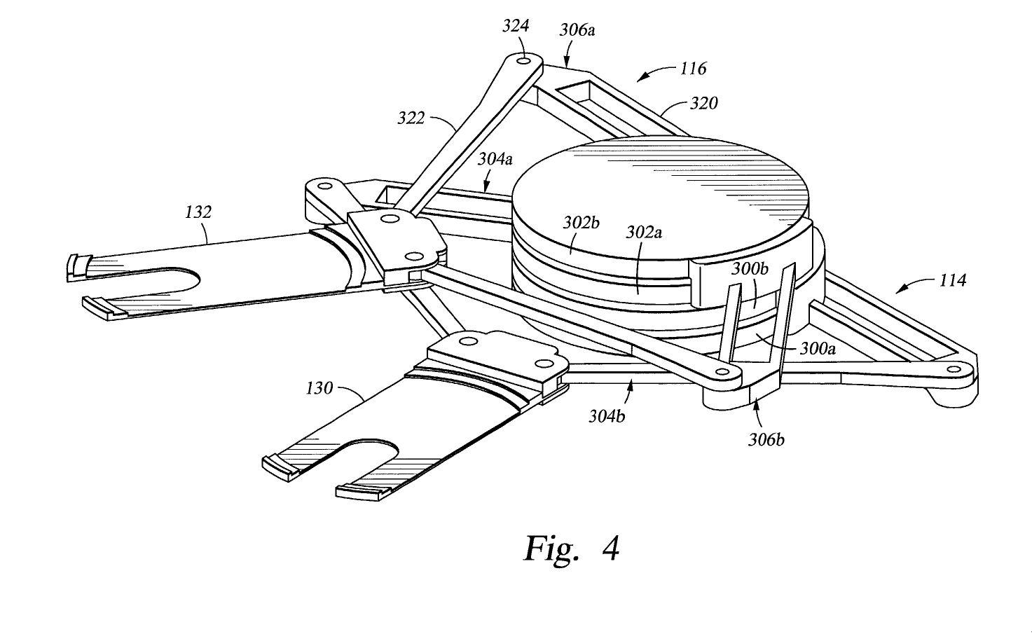

FIG. 4 is a perspective view illustrating one embodiment of a pair of robots 114, 116 in a partially retracted position. In this embodiment, the robots 114, 116 utilize magnetic coupling to enable movement and are stacked concentrically about a common axis of rotation in the transfer chamber 110. As OUI robots, the robots 114, 116 in this configuration are separately operable. It is to be understood, however, that the invention can be used with other types of robots, including robots that are not concentric. Each robot 114, 116 may include a pair of rotating hubs 300a-b, 302a-b connected to an actuator (not shown) and a pair of frog leg arms 304a-b, 306a-b mounting a blade 130, 132 thereon. Each frog leg arm may include two linkages 320, 322 pivotally connected at a pivot joint 324. Each robot 114, 116 is capable of moving the blade 130, 132 mounted thereto linearly by extension and retraction of the frog leg arms 304a-b, 306a-b and rotationally by rotation of the frog leg arms 304a-b, 306a-b about the hubs 300a-b, 302a-b to transport wafers positioned on a blade throughout system 100. The system controller 120 (shown and described with reference to FIG. 2) is programmed to operate the robots 114, 116 in a time optimal sequence that results in the desired movement of wafers through the system. A robot similar to those described with reference to FIG. 4 is the VHP® robot described in U.S. patent application Ser. No. 09/015,726, filed on Jan. 29, 1998, which is herein incorporated by reference in its entirety.

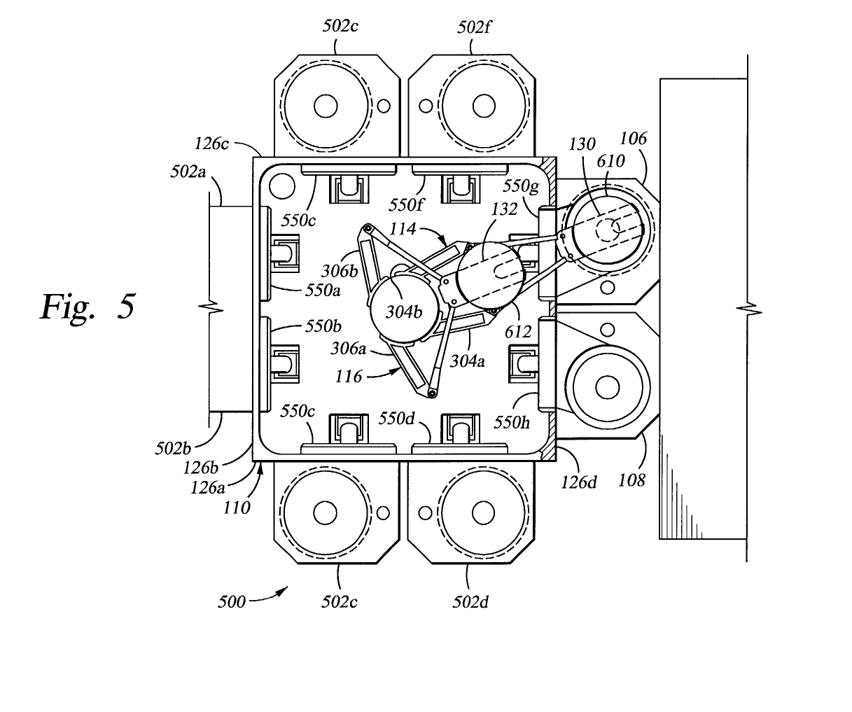

The operation of one embodiment of the invention is described below with reference to a processing system 500 depicted in FIGS. 5-7. The system 500 is generally configured similar to the system 100 described above. A first load lock chamber 106 is loaded with a wafer cassette 104 or individual wafers are loaded into the cassette disposed in the loadlock chamber 106. The first load lock chamber 106 is pumped down to a pressure about equal to the pressure within the transfer chamber 110. The slit valve (not shown) on the transfer side of the load lock chamber 106 is then opened to allow transfer of wafers between the load lock chamber 106 and the transfer chamber 110. As this process is proceeding, the second load lock chamber 108 is loaded and pumped down to about the pressure of the transfer chamber 110. The second load lock chamber 108 is then ready to supply wafers to the transfer chamber 110.

To retrieve wafers, the robots 114, 116 are extended into the first load lock chamber 106 either separately or simultaneously to retrieve a pair of wafers. For example, a single wafer may be retrieved from the load lock chamber 106 by a single robot without extension of the blade of the other robot into the load lock chamber 106. Alternatively, a pair of wafers may be simultaneously retrieved from the load lock chamber 106 by simultaneous extension of the blades 130, 132 of both robots 114, 116. FIG. 5 shows a top plan view of the processing system 500 showing angular extension relative the wall 126 of the chamber 110 of the blade 130 of one robot 114 through an opening 550g into load lock chamber 106 for retrieval or placement of a wafer 610. The second robot 116 has a wafer 612 supported on the blade 132 and is shown in a retracted position.

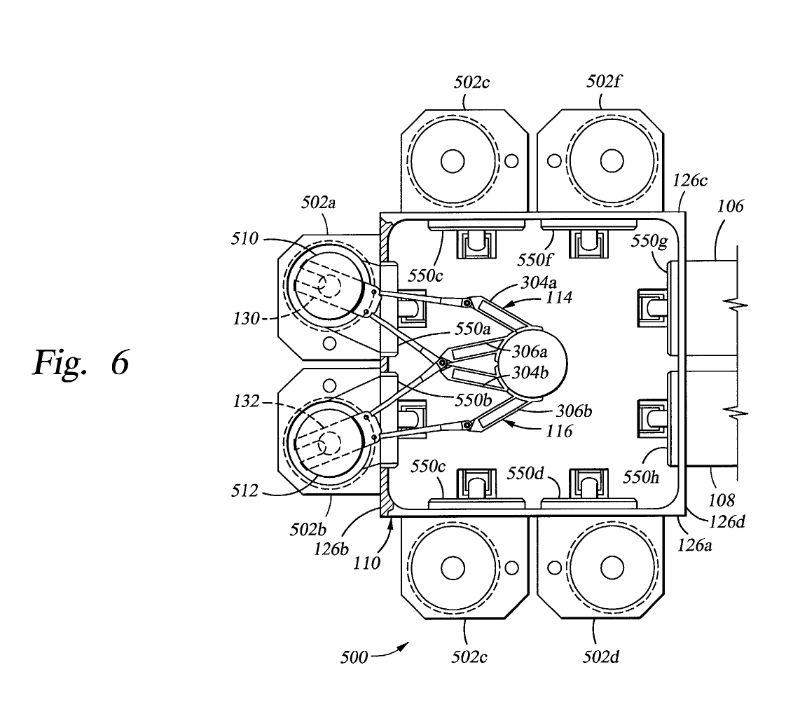

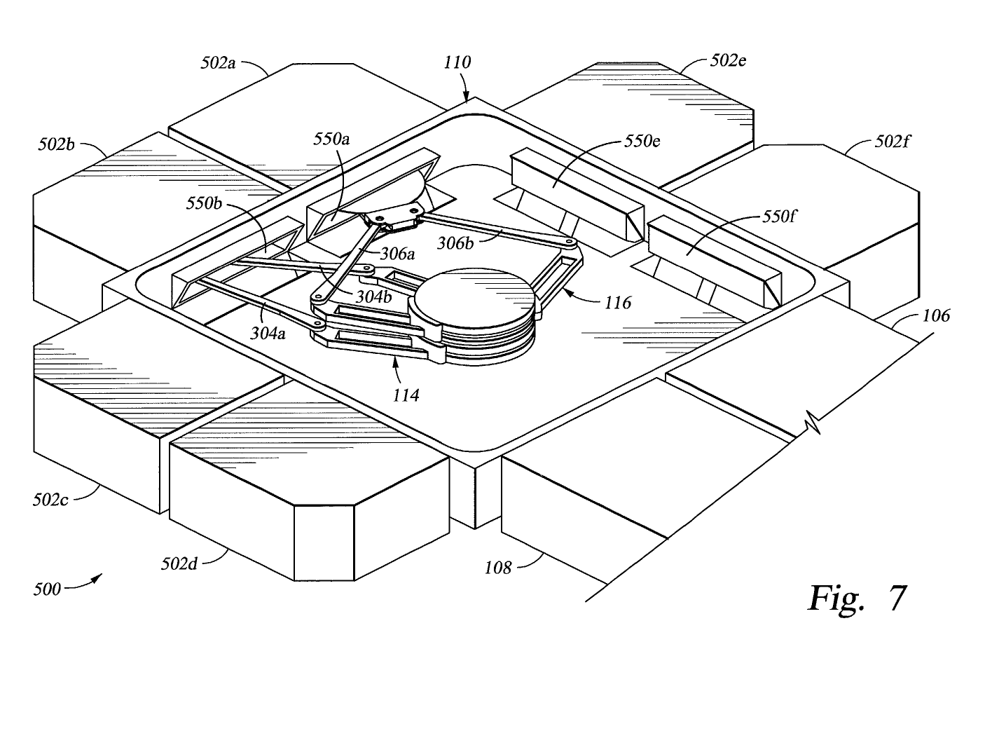

To perform wafer transfer, each robot 114, 116 rotates into a position to allow angular extension into the load lock chamber 106 and then extends angularly through opening 550g into the load lock chamber 106 below a wafer and the wafer cassette 104 is moved, or indexed, within the load lock chamber 106 to deliver a wafer onto each blade 130, 132. The arms 304a-b, 306a-b of the robots 114, 116 are then retracted to remove the wafer on each blade 130, 132 from the wafer cassette 104 and from the load lock chamber 106. The robots 114, 116 then rotate to position the wafers for transfer into processing chambers 502a-f. The arms 304a-b, 306a-b of each robot 114, 116 are then extended to position a wafer in each processing chamber 502a-f, as shown in FIGS. 6 and 7.

In FIG. 6, simultaneous placement or retrieval of wafers 510, 512 into a pair of processing regions 502a-b is shown. Robots 114, 116 are shown angularly extended through openings 550a and 550b into processing regions 502a and 502b, respectively. Alternatively, the robots 114, 116 may act separately so that one blade at a time is inserted into a processing chamber. For example, one robot may extend the blade thereof into a processing chamber 502a-b while the other robot is in an at least partially retracted position so that the blade thereof is not extended into a chamber as shown in FIG. 7. Therefore, in a system such as system 500 that includes pairs of adjacent processing chambers 502a-f, if one of a pair of processing chambers disposed on one of the walls 126a-d is not operational, the independent operation of the robots 114, 116 allows one robot to access an operational processing chamber without a second robot accessing the nonoperational processing chamber in the pair. Therefore, the second robot is free to perform some other task while the first robot accesses the operational processing chamber of the pair, such as placing or retrieving a wafer in a processing chamber disposed along another wall, or placing or retrieving a wafer from one of the load lock chambers 106, 108.

FIG. 7 is a perspective view of the transfer chamber 110 of system 100 illustrating the robots 114, 116, respectively, in an extended and partially extended position. As shown in FIG. 7, each robot 114, 116 is extended through openings 550a-b into separate adjacent processing chambers 502a-b.

After wafers are positioned on substrate support members (not shown) or other support within each processing chamber 502a, 502b for processing, the arms 304a-b, 306a-b are retracted and the robots 114, 116 rotated back towards the first load lock chamber 106 to retrieve another pair of wafers or retrieve processed wafers from other process chambers for placement back within the load lock chamber 106. Another pair of wafers is then retrieved for the load lock chamber 106 and each wafer is inserted into two of the processing chambers 502c-f in the manner described above. After wafers are processed, the robots 114, 116 rotate into a position and extend to retrieve the wafers from the respective processing chamber. The wafers are loaded onto the blades 130,132, then the blades 130, 132 retract to remove the wafers from the processing chamber, and then the robots 114, 116 rotate into a position in which the blades 130, 132 of each robot 114, 116 can be inserted into the load lock chamber 106 to place the processed wafers therein. Optionally, one wafer may be returned to each of the load locks 106,108.

After the wafer cassette 104 in load lock chamber 106 contains only returned, processed wafers, the other load lock chamber 108 is accessed by the robots 114, 116 without waiting for the wafers within the load lock 106 to be exchanged for another batch of wafers. During this time, load lock chamber 106 is vented up to attain atmospheric pressure, the processed wafers are removed therefrom, and new wafers to be processed are inserted therein. Since at least one of the load lock chambers 106, 108 is available at any given time for wafer access by the robots 114, 116, continuous processing and corresponding high throughput of wafers is achieved.

The independent operability of the robots 114, 116 shown in FIGS. 1-7 enables several different modes of operation that will be described below. However, the modes of operation described below are not meant to be limiting and the invention contemplates modes of operation of the robots 114, 116 other than those described below.

In one mode of operation, the robots 114, 116 first rotate into a position to allow angular extension of both of the blades 130, 132 into a single load lock chamber 106 or 108. Next, the robots 114, 116 simultaneously extend through a single opening 550g or 550h into a single load lock chamber 106 or 108. Each robot 114, 116 extends to position the blade 130, 132 on a different vertical plane and below a different wafer in a single wafer cassette within the load lock chamber and the wafer cassette is moved, or indexed, within the load lock chamber to deliver a wafer onto each blade 130, 132. Next, the arms 304a-b, 306a-b of each robot 114, 116 are retracted to remove the wafer on each blade 130, 132 from the wafer cassette and from the load lock chamber, and each robot 114, 116 rotates into position to insert each wafer into a different processing chamber. Next, the arms 304a-b, 306a-b of each robot 114, 116 are simultaneously extended to position the blades 130, 132 into separate adjacent or nonadjacent processing chambers (i.e., the adjacent chambers are disposed on the same wall or facet) or regions to place the wafers therein for processing (as shown and described with reference to FIG. 6).

Following processing, the robots 114, 116 simultaneously retrieve the wafers from the two processing chambers or regions, then each robot 114, 116 rotates into position to simultaneously place the wafers located on the blades 130, 132 thereof into a load lock chamber 106, 108. The robots 114, 116 extend through a single opening 550g or 550h into a load lock chamber. Each robot 114, 116 extends to position the blade 130, 132 thereof on a different vertical plane to position each wafer above a different wafer seat in a wafer cassette within the load lock chamber. Next, the wafer cassette is moved, or indexed, within the load lock chamber to lift each wafer from the robot blades 130, 132 and position each wafer on a different wafer seat in the wafer cassette.

In another mode of operation, the robots 114, 116 could retrieve wafers from a single load lock chamber 106 or 108 at different times, so that one robot 114 extends the blade thereof into the load lock chamber 106 to retrieve a wafer while the other robot 116 is in at least partially retracted position so that the blade 132 thereof does not extend into a chamber (as shown in FIG. 5). The robots 114, 116 could similarly place and later retrieve wafers from processing chambers at different time.

In still another mode of operation, a first robot 114 could insert the blade 130 thereof into a first load lock chamber to retrieve a wafer while a second robot 116 simultaneously inserts the blade 132 thereof into a processing chamber to place or retrieve a wafer. Next, the first robot 114 could rotate into position and place or retrieve a wafer from the first load lock chamber while the second robot 116 moves and places or retrieves a wafer from a processing chamber.

Although specific reference has been made to the embodiment of the robots 114, 116 shown in FIG. 5, it is to be understood that other configurations may be devised having one or more robots capable of extending into a chamber at an acute angle a wall disposed therebetween. For example, the invention could be used with two or more single-armed robots such as VHP® robots, as described in the previously-incorporated U.S. patent application Ser. No. 09/015,726. Furthermore, the concept of having two robots simultaneously access a load lock can be extended to any number of robots, e.g., a plurality of robots including 2, 3, 4 or more robots, two or more robots positioned concentrically and/or parallel central axises.

While foregoing is directed to the preferred embodiment of the present invention, other and further embodiments of the invention may be devised without departing from the basic scope thereof, and the scope thereof is determined by the claims that follow.

What is claimed is:

1. A system for transferring wafers between chambers, the system comprising:
a transfer chamber having a first sidewall;
a first chamber abutting the first sidewall of the transfer chamber and having a first sealable wafer transfer port disposed therebetween, the first chamber having a wafer receiving member disposed therein and adapted to support the wafer centered on a central axis of the wafer receiving member; and
at least a first transfer robot disposed in the transfer chamber and having a central axis of rotation, that first transfer robot having a first wafer support blade that travels along a path defined between the central axis of the robot and central axis of the wafer receiving member, the path disposed at an acute angle relative to the first sidewall.

2. The system of claim 1, wherein the first chamber is a load lock chamber.

3. The system of claim 1, wherein the first chamber is a process chamber.

4. The system of claim 1 further comprising:
a plurality of process chamber coupled to the transfer chamber.

5. The system of claim 1, wherein the transfer chamber further comprises:
a second transfer robot disposed in the transfer chamber and having a second wafer support blade.

6. The system of claim 5, wherein the first wafer support blade and the second wafer support blade are disposed in different and parallel operational planes.

7. The system of claim 1, wherein the transfer chamber further comprises:
a second transfer robot disposed in the transfer chamber concentric with the first robot.

8. The system of claim 1 further comprising:
a second chamber abutting the first sidewall of the transfer chamber and having a second sealable wafer transfer port disposed therebetween, the second chamber having a wafer receiving member disposed therein and adapted to support the wafer centered on a central axis of the wafer receiving member, wherein the blade of the first robot travels along a path defined between the central axis of the robot and central axis of the wafer receiving member, the path disposed at an acute angle relative to the first sidewall.

9. The system of claim 8, wherein the transfer chamber further comprises:
at least a second transfer robot disposed in the transfer chamber and concentric with the central axis of rotation of the first transfer robot;
a first pair of process chambers abutting a second sidewall of the transfer chamber; and
a second pair of process chambers abutting a third sidewall of the transfer chamber.

10. The system of claim 9, wherein each process chamber includes a wafer receiving member disposed therein and adapted to support the wafer centered on a central axis of the wafer receiving member, wherein the blade of the first robot travels along a path defined between the central axis of the robot and central axis of the wafer receiving member, the path disposed at an acute angle relative to the first sidewall.

11. The system of claim 1, wherein the port disposed between the transfer chamber and the first chamber is not centered relative to a line passing through the central axis of the wafer receiving member and perpendicular to the first sidewall.

12. A system for transferring wafers between chambers, the system comprising:
a transfer chamber having a first sidewall;
a first transfer robot disposed in the transfer chamber and having a central axis of rotation, the first robot has a first wafer support blade disposed in a first operational plane;
a second transfer robot independently operable from and disposed in the transfer chamber concentric with the first robot, the second robot has a second wafer support blade disposed in a second operational plane that is different and parallel to the first operational plane; and
a first chamber abutting the first sidewall of the transfer chamber and having a first sealable wafer transfer port disposed therebetween, the first chamber having a wafer receiving member disposed therein and adapted to support the wafer centered on a central axis of the wafer receiving member, wherein the blade of the first robot travels along a path defined between the central axis of the robot and central axis of the wafer receiving member, the path disposed at an acute angle relative to the first sidewall.

13. The system of claim 12, wherein the first chamber is a load lock chamber or a process chamber.

14. The system of claim 12 further comprising:
a plurality of process chamber coupled to the transfer chamber.

15. The system of claim 12 further comprising:
a second chamber abutting the first sidewall of the transfer chamber and having a sealable wafer transfer port disposed therebetween, the second chamber having a wafer receiving member disposed therein and adapted to support the wafer centered on a central axis of the wafer receiving member, wherein the blade of the first robot travels along a path defined between the central axis of the robot and central axis of the wafer receiving member, the path disposed at an acute angle relative to the first sidewall.

16. The system of claim 12 further comprising:
a first pair of process chambers abutting a second sidewall of the transfer chamber; and
a second pair of process chambers abutting a third sidewall of the transfer chamber.

17. The system of claim 16, wherein each process chamber includes a wafer receiving member disposed therein and adapted to support the wafer centered on a central axis of the wafer receiving member, wherein the blade of the first robot travels along paths defined between the central axis of the robot and central axis of each wafer receiving member, the paths disposed at an acute angle relative to the respected sidewall disposed therebetween.

18. The system of claim 12, wherein the port disposed between the transfer chamber and the first chamber is not centered relative to a line passing through the central axis of the wafer receiving member and perpendicular to the first sidewall.

19. A system for transferring wafers between chambers, the system comprising:
a transfer chamber having a first sidewall;
a first transfer robot disposed in the transfer chamber and having a first blade disposed on a first operational plane;
a second transfer robot independently operable relative to the first transfer robot, the second transfer robot disposed in the transfer chamber and having a second blade disposed on a second operational plane parallel to the first operational plane;
a first chamber abutting the first sidewall of the transfer chamber and having a first sealable wafer transfer port disposed therebetween, the transfer port configured to allow the first blade and the second blade to pass therethrough simultaneously.

20. The system of claim 19, wherein the first and the second transfer robots have a concentric axis of rotation.

21. The system of claim 19, wherein the first chamber further comprises:
a wafer receiving member disposed therein and adapted to support the wafer centered on a central axis of the wafer receiving member, wherein the blade of the first robot travels along a path defined between the central axis of the robot and central axis of the wafer receiving member, the path disposed at an acute angle relative to the first sidewall.

22. A system for transferring wafers between chambers, the system comprising:
a transfer chamber having a first sidewall;
a first transfer robot disposed in the transfer chamber and having a first blade disposed on a first operational plane;
a second transfer robot disposed in the transfer chamber concentric to and independently operable from the first robot, the second robot having a second blade disposed on a second operational plane different and parallel to the first operational plane; and
a first chamber abutting the first sidewall of the transfer chamber and having a first sealable wafer transfer port disposed therebetween, the first chamber having a wafer receiving member disposed in the first chamber and adapted to support the wafer centered on a central axis of the wafer receiving member, wherein the blade of the first robot travels along a path defined between the central axis of the robot and central axis of the wafer receiving member, the path disposed at an acute angle relative to the first sidewall; and
a second chamber abutting the first sidewall of the transfer chamber adjacent the first chamber and having a second sealable wafer transfer port disposed therebetween, the second chamber having a wafer receiving member disposed in the second chamber and adapted to support the wafer centered on a central axis of the wafer receiving member, wherein the blade of the first robot travels along a path defined between the central axis of the robot and central axis of the wafer receiving member, the path disposed at an acute angle relative to the first sidewall.

23. The system of claim 22 further comprising:
a third chamber abutting a second sidewall of the transfer chamber and having a sealable wafer transfer port disposed therebetween, the transfer port configured to allow the first blade and the second blade to pass therethrough simultaneously.

24. The system of claim 22 further comprising:
a third chamber abutting a second sidewall of the transfer chamber and having a sealable wafer transfer port disposed therebetween, the transfer port configured to allow the first blade and the second blade of the first and second robots to pass therethrough simultaneously; and
a fourth chamber abutting the second sidewall of the transfer chamber and having a sealable wafer transfer port disposed therebetween, the transfer port configured to allow the first blade and the second blade to pass therethrough simultaneously.

25. The system of claim 24, wherein the third and fourth chambers each further comprise:
a wafer receiving member disposed therein and adapted to support the wafer centered on a central axis of the wafer receiving member, wherein the blade of the first robot travels along paths defined between the central axis of the first robot and central axis of the wafer receiving member of the third and fourth chambers, each path disposed at an acute angle relative to the second sidewall.

26. The system of claim 24 further comprising:
a fifth chamber abutting a third sidewall of the transfer chamber and having a sealable wafer transfer port disposed therebetween, the transfer port configured to allow the first blade and the second blade of the first and second robots to pass therethrough simultaneously; and
a sixth chamber abutting the third sidewall of the transfer chamber and having a sealable wafer transfer port disposed therebetween, the transfer port configured to allow the first blade and the second blade to pass therethrough simultaneously.

27. The system of claim 26 wherein the third, fourth, fifth and sixth chambers each further comprise:
a wafer receiving member disposed therein and adapted to support the wafer centered on a central axis of the wafer receiving member, wherein the blade of the first robot travels along paths defined between the central axis of the first robot and central axis of the wafer receiving member of the third, fourth, fifth and sixth chambers, each path disposed at an acute angle relative to the second or a third sidewall of the transfer chamber, respectively.

28. A method of transferring wafers between chambers, comprising:
providing a transfer chamber having a first transfer robot disposed therein, the transfer chamber having a first wall containing an aperture for accessing a first chamber; and
extending a first blade of the first wafer transfer robot at an acute angle relative to the first wall of the transfer chamber along a path from a retracted position within the transfer chamber to an extended position in the first chamber.

29. The method of claim 28 further comprising:
extending a second blade of a second wafer transfer robot disposed in the transfer chamber along a path parallel to the path of the first wafer transfer robot.

30. The method of claim 28 further comprising:
moving the elevation of a wafer storage cassette disposed in the first chamber so that the first and second blades interface with predetermined wafer seats of the cassette.

31. The method of claim 30 further comprising:
providing a second chamber disposed proximate the first wall of the transfer chamber, the first wall having a second aperture for accessing the second chamber; and
extending the first blade of the first wafer transfer robot at an acute angle relative to the first wall of the transfer chamber along a path from a retracted position within the transfer chamber to an extended position in the second chamber.

32. The method of claim 31 further comprising:
providing a third chamber disposed proximate a second wall of the transfer chamber, the third wall having a third aperture for accessing the third chamber; and
extending the first blade of the first wafer transfer robot at an acute angle relative to the third wall of the transfer chamber along a path from a retracted position within the transfer chamber to an extended position in the third chamber.

33. The method of claim 31 further comprising:
providing a third chamber disposed proximate a second wall of the transfer chamber, the third wall having a third aperture for accessing the third chamber;
extending the first blade of the first wafer transfer robot at an acute angle relative to the third wall of the transfer chamber along a path from a retracted position within the transfer chamber to an extended position in the third chamber; and
extending the second blade of a second wafer transfer robot at an acute angle relative to the third wall of the transfer chamber along a path from a retracted position within the transfer chamber to an extended position in the third chamber.

34. The method of claim 33, wherein the steps of extending the first and the second blades occur simultaneously.

35. A method of transferring wafers between chambers, comprising:
providing a transfer chamber abutting a first chamber, the transfer chamber having a first wafer transfer robot and a second transfer robot concentrically disposed therein, the first chamber having a first port, and second port and a plurality of vertically stacked wafers disposed therein;
pumping down the first chamber to a pressure substantially equal to a pressure of the transfer chamber;
retrieving a first wafer from the wafer stack on a first blade of the first robot through the second port into the transfer chamber on a first plane; and
retrieving a second wafer from the wafer stack on a second blade of the second robot through the second port on a second plane different from and parallel to the first plane.

36. The method of claim 35, wherein the steps of retrieving the first and the second wafers occur simultaneously.

37. The method of claim 35, wherein the step of extending the first blade further comprises moving an acute angle relative to a first wall of the transfer chamber between a retracted position within the transfer chamber and an extended position in the first chamber.

38. A method of transferring wafers between chambers comprising:
providing a transfer chamber having a first wafer transfer robot and a second transfer robot concentrically disposed therein, the transfer chamber having a first wall containing a first port for accessing a first chamber and a second port for accessing a second chamber;
extending a first blade of the first robot at an acute angle relative to the first wall of the transfer chamber between a retracted position within the transfer chamber and an extended position in the first chamber through the first port on a first plane;
extending a second blade of the second robot at an acute angle relative to the first wall of the transfer chamber between a retracted position within the transfer chamber and an extended position in the second chamber through the second port on a second plane different from and parallel to the first plane;
returning the first and the blades to the retracted position; and
extending the first blade of the first robot and the second blade of the second robot at an acute angle relative to a second wall of the transfer chamber between a retracted position within the transfer chamber and an extended position in a second chamber through a third port disposed on the second wall of the transfer chamber.

39. The method of claim 38 further comprising:
sealing the second chamber from the transfer chamber;
venting the second chamber to remove wafers therefrom; and
extending the first blade of the first robot and the second blade of the second robot at an acute angle relative to the second wall of the transfer chamber between a retracted position within the transfer chamber and an extended position in a third chamber through a fourth port disposed on the second wall of the transfer chamber.

40. The method of claim 39 further comprising:
sealing the third chamber from the transfer chamber;
venting the third chamber to remove wafers therefrom;
pumping down the second chamber; and
extending the first blade of the first robot and the second blade of the second robot into the second chamber to retrieve wafers to be processed.
